(19) United States
(12) Patent Application Publication
(10) Pub. No.: US 2025/0359092 A1
(43) Pub. Date: Nov. 20, 2025

(54) CAPACITOR STRUCTURES AND METHODS OF FORMING THEREOF

(71) Applicant: GlobalFoundries Singapore Pte. Ltd., Singapore (SG)

(72) Inventor: ANTHONY JEREMY VILLALON, Singapore (SG)

(21) Appl. No.: 18/666,804

(22) Filed: May 16, 2024

(51) Int. Cl. H01L 23/522; H01L 27/08

(52) U.S. Cl. CPC H10D 1/696; H01L 23/5223; H10D 84/212

(57) ABSTRACT

A structure including a first dielectric layer having a tapered portion over a substrate is provided. The tapered portion includes a first side surface and a second side surface. A metal-insulator-metal (MIM) capacitor stack is arranged over the tapered portion of the first dielectric layer. The MIM capacitor stack includes a first electrode layer arranged over the first side surface and the second side surface of the tapered portion, a capacitor dielectric arranged over the first electrode layer over the first side surface and the second side surface of the tapered portion and a second electrode layer arranged over the capacitor dielectric over the first side surface and the second side surface of the tapered portion.

### TECHNICAL FIELD

The present disclosure relates generally to integrated circuits, and more particularly to structures including metal-insulator-metal capacitors and methods of forming structures including metal-insulator-metal capacitors.

### BACKGROUND

As electronic components have become smaller, more of them can be integrated onto a single chip. Alongside transistors and other active components, passive components such as resistors, capacitors, and inductors are being integrated in semiconductor devices. The integration of passive components has played a role in expanding the capabilities of integrated circuits (ICs), enabling the development of more efficient and versatile electronic systems. For example, the integration of capacitors into ICs has enabled the development of DC-DC converters such as in Radio Frequency (RF) circuits, decoupling circuitry, etc. In the case of a metal-insulator-metal capacitor, the performance of the capacitors may be increased, for example, by introducing a third electrode, however, this may undesirably use up more of the footprint of the IC. In other approaches for improving the performance of the capacitors, the thickness of the dielectric sandwiched between the two electrode layers of the metal-insulator-metal capacitor have been reduced, however, this approach is limited by the device reliability considerations. Accordingly, it is desirable to provide improved capacitor structures and methods of forming thereof.

### SUMMARY

According to various embodiments, a structure including a first dielectric layer having a tapered portion over a substrate is provided. The tapered portion includes a first side surface and a second side surface. A metal-insulator-metal (MIM) capacitor stack is arranged over the tapered portion of the first dielectric layer. The MIM capacitor stack includes a first electrode layer arranged over the first side surface and the second side surface of the tapered portion, a capacitor dielectric arranged over the first electrode layer over the first side surface and the second side surface of the tapered portion and a second electrode layer arranged over the capacitor dielectric over the first side surface and the second side surface of the tapered portion.

According to another aspect, a structure including a first dielectric layer over a substrate and a groove having first and second side surfaces and a bottom surface in the first dielectric layer is provided. The first and second side surfaces are sloped and the groove tapers from an upper portion to a lower portion of the groove. A metal-insulator-metal (MIM) capacitor stack is arranged over the first dielectric layer and conformal to the groove. The MIM capacitor stack includes a first electrode layer lining the first and second side surfaces and the bottom surface of the groove, a capacitor dielectric arranged over and lining the first electrode layer in the groove and a second electrode layer arranged over and lining the second electrode layer in the groove.

According to various embodiments, a method of forming a structure is provided. The method includes forming a first dielectric layer over a substrate, and forming a tapered portion of the first dielectric layer. The tapered portion includes a first side surface and a second side surface. The method may include forming a metal-insulator-metal (MIM) capacitor stack over the tapered portion of the first dielectric layer. The MIM capacitor stack includes a first electrode layer formed over the first side surface and the second side surface of the tapered portion, a capacitor dielectric formed over the first electrode layer over the first side surface and the second side surface of the tapered portion and a second electrode layer formed over the capacitor dielectric over the first side surface and the second side surface of the tapered portion.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following:

FIGS. 1A-1B illustrate cross-sectional views of embodiments of a structure;

FIGS. 2A-2H show cross-sectional views of a process for forming a structure; and

FIGS. 3A-3E show cross-sectional views of another process for forming a structure.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the embodiments. Other embodiments may be utilized and structural, logical, and electrical changes may be made without departing from the scope of the invention. The various embodiments are not necessarily mutually exclusive, as some embodiments can be combined with one or more other embodiments to form new embodiments.

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

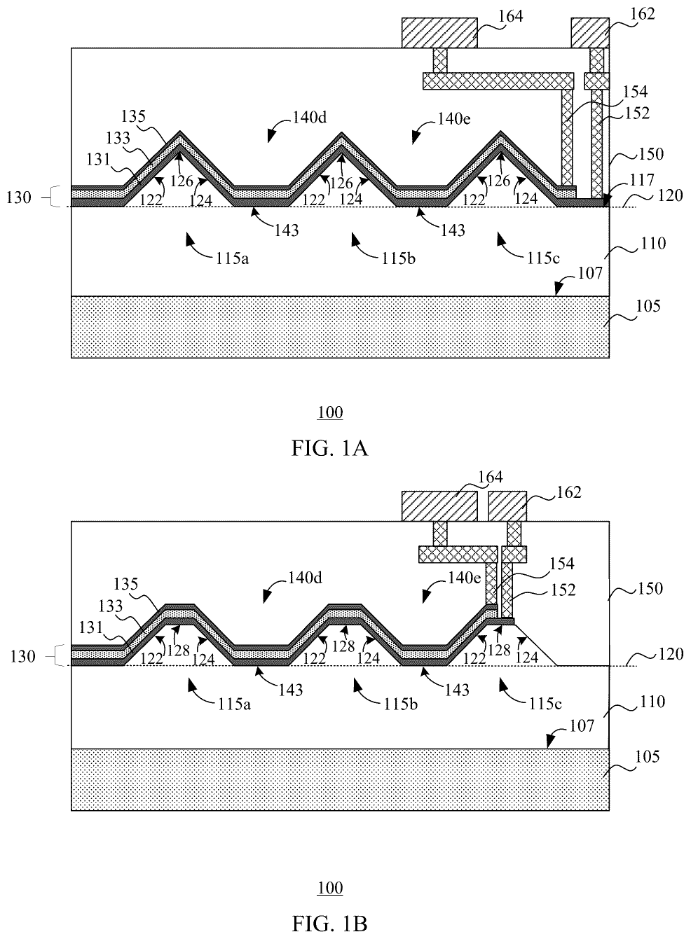

FIGS. 1A-1B illustrate cross-sectional views of embodiments of a structure 100. The structure 100 includes a first dielectric layer 110 over a substrate 105. The substrate 105 may be a semiconductor substrate, such as a silicon substrate or crystal-on-insulator (COI) (e.g., silicon-on-insulator (SOI)) substrate. The first dielectric layer 110 may be formed of a dielectric material, such as silicon oxide, silicon nitride, low-k dielectric (e.g., SiCOH) in a back-end-of-line (BEOL) process. In one embodiment, the first dielectric layer 110 may have one or more tapered portions, such as tapered portions 115a, 115b and 115c. FIGS. 1A and 1B illustrate three tapered portions 115a, 115b and 115c, however, it is understood that any number of tapered portions is applicable. A tapered portion of the first dielectric layer 110, such as each of the tapered portions 115a, 115b and 115c, may have a first side surface 122 and a second side surface 124. The first side surface 122 and the second side surface 124 may be sloped surfaces and have an angle of inclination with respect to a reference plane 120 which is parallel to a top surface 107 of the substrate 105. In one embodiment, the angle of inclination of the first side surface 122 and the second side surface 124 may be an acute angle. In one embodiment, the acute angle may range from about 30° or greater and less than about 70°. In another embodiment, the acute angle may range from about 45° or greater and less than about 60°. A width (from the first side surface 122 to the second side surface 124) of each of the tapered portions 115a, 115b and 115c gradually narrows from a lower portion (e.g., nearer to the substrate 105) of the tapered portion towards an upper portion (e.g., further away from the substrate 105) of the tapered portion. Accordingly, the lower portion is wider than the upper portion of each of the tapered portions 115a, 115b and 115c. In other words, a lower width of the lower portion is greater than an upper width of the upper portion of each of the tapered portions 115a, 115b and 115c.

In one embodiment, the second side surface 124 may adjoin the first side surface 122 of a respective tapered portion 115a, 115b or 115c to form a corner or edge 126 of the respective tapered portion 115a, 115b or 115c, as illustrated in FIG. 1A. A cross-section of the tapered portions 115a, 115b and 115c of the first dielectric layer 110, for example, may have a triangular shape, as illustrated in FIG. 1A. In another embodiment, a tapered portion of the first dielectric layer 110, such as each of the tapered portions 115a, 115b and 115c may have a substantially flat top surface 128, and the first side surface 122 and the second side surface 124 may adjoin the top surface 128 of the tapered portion, as illustrated in FIG. 1B. In such cases, a cross-section of the tapered portions 115a, 115b and 115c of the first dielectric layer 110 may have a trapezoidal shape.

In one embodiment, grooves or openings 140d and 140e may be arranged in the first dielectric layer 110. A groove or opening in the first dielectric layer 110, such as the grooves 140d and 140e, may have sloped or slanted side surfaces and may taper (e.g., gradual narrowing) from an upper portion to a lower portion of the groove. In other words, the upper portion of the grooves 140d and 140e may be wider than the lower portion of the grooves 140d and 140e. The groove 140d may be between the immediately adjacent tapered portions 115a and 115b of the first dielectric layer 110. The groove 140d may be defined by at least the first side surface 122 of the tapered portion 115b and the second side surface 124 of the tapered portion 115a. In other words, the first side surface 122 of the tapered portion 115b and the second side surface 124 of the tapered portion 115a may be, or form, side surfaces of the groove 140d. As for the groove 140e, it may be between the immediately adjacent tapered portions 115b and 115c of the first dielectric layer 110. The groove 140e may be defined by at least the second side surface 124 of the tapered portion 115b and the first side surface 122 of the tapered portion 115c. In other words, the second side surface 124 of the tapered portion 115b and the first side surface 122 of the tapered portion 115c may be, or form, side surfaces of the groove 140e. In one embodiment, the grooves 140d and 140e may be trenches which taper from an upper portion to a lower portion of the trenches. The first side surface 122 and the second side surface 124 defining a respective groove 140d or 140e may adjoin a bottom surface 143 of the respective groove 140d or 140e in the first dielectric layer 110. The bottom surface 143 may be substantially flat. In other embodiments, the grooves 140d and 140e may not have bottom surface 143, and in such cases, the first side surface 122 and the second side surface 124 defining a respective groove 140d or 140e may adjoin each other to form a corner or edge of the respective groove 140d or 140e (not shown).

A metal-insulator-metal (MIM) capacitor stack 130 may be arranged over the first dielectric layer 110. In one embodiment, the MIM capacitor stack 130 may include a first electrode layer 131, a capacitor dielectric 133 and a second electrode layer 135. In one embodiment, the MIM capacitor stack 130 may be arranged over at least a tapered portion, such as the tapered portions 115a, 115b and 115c, of the first dielectric layer 110, and the first electrode layer 131 may be arranged over the first side surface 122 and the second side surface 124 of the tapered portion, the capacitor dielectric 133 may be arranged over the first electrode layer 131 over the first side surface 122 and the second side surface 124 of the tapered portion, and the second electrode layer 135 may be arranged over the capacitor dielectric 133 over the first side surface 122 and the second side surface 124 of the tapered portion. In the case where the grooves 140d and 140e have bottom surface 143, the MIM capacitor stack 130 may further extend over the bottom surface 143 of the groove 140d and the bottom surface 143 of the groove 140e. The first electrode layer 131, the capacitor dielectric 133 and the second electrode layer 135 each may be arranged over the bottom surface 143 of the respective groove 140d and groove 140e. The first electrode layer 131 may be conformal to at least a tapered portion, such as the tapered portions 115a, 115b and 115c, of the first dielectric layer 110, the capacitor dielectric 133 may be conformal to the first electrode layer 131 over the tapered portion, and the second electrode layer 135 may be conformal to the capacitor dielectric 133 over the tapered portion. The term “conformal” may refer to when a material layer conforms to or follows the contours of the surface that the material layer is in direct contact with. For example, the first electrode layer 131 may follow the contours of the first and second side surfaces 122 and 124 of the tapered portions 115a, 115b and 115c of the first dielectric layer 110. In the case where the first side surface 122 and the second side surface 124 of a tapered portion adjoin each other to form a corner 126, the MIM capacitor stack 130 may follow the contours of the first side surface 122, the corner 126 and the second side surface 124 of the tapered portion of the first dielectric layer 110, as illustrated in FIG. 1A. In the case where a tapered portion has a top surface 128 and the first side surface 122 and the second side surface 124 of the tapered portion adjoin the top surface 128, the MIM capacitor stack 130 may follow the contours of the first side surface 122, the top surface 128 and the second side surface 124 of the tapered portion of the first dielectric layer 110, as illustrated in FIG. 1B.

In one embodiment, the MIM capacitor stack 130 may be arranged over a groove, such as the grooves 140d and 140e, of the first dielectric layer 110, and may be conformal to the groove. The first electrode layer 131 may be conformal to the groove, the capacitor dielectric 133 may be conformal to the first electrode layer 131 over the groove and the second electrode layer 135 may be conformal to the capacitor dielectric 133 over the groove. As illustrated in FIGS. 1A and 1B, the first electrode layer 131 may be lining the first and second side surfaces 122 and 124 and the bottom surface 143 of the grooves 140d and 140e, the capacitor dielectric 133 may be arranged over and lining the first electrode layer 131 in the grooves 140d and 140e, and the second electrode layer 135 may be arranged over and lining the capacitor dielectric 133 in the grooves 140d and 140e.

Referring to FIG. 1A, in one embodiment, the first dielectric layer 110 may include a flat surface portion having a substantially flat surface 117. In one embodiment, the MIM capacitor stack 130 may further extend over the flat surface portion having the flat surface 117. The capacitor dielectric 133 and the second electrode layer 135 may partially overlap the first electrode layer 131 over the flat surface portion. A top surface of a portion of the first electrode layer 131 over the flat surface portion which is not overlapped by the capacitor dielectric 133 and the second electrode layer 135 may be exposed for coupling to interconnection 162.

The first electrode layer 131 and the second electrode layer 135 may be formed of an electrically conductive material such as copper. The capacitor dielectric 133 may be formed of a dielectric material such as silicon oxide, silicon nitride, or silicon oxynitride.

A second dielectric layer 150 may be arranged over the MIM capacitor stack 130 and the first dielectric layer 110. The second dielectric layer 150 may fill a remaining space in the grooves 140d and 140e. The second dielectric layer 150 may be formed of a dielectric material, such as silicon oxide, silicon nitride, low-k dielectric (e.g., SiCOH) in the BEOL process. Contacts 152 and 154 may be arranged in the second dielectric layer 150. The contact 152 may couple the first electrode layer 131 to interconnection 162. The contact 154 may couple the second electrode layer 135 to interconnection 164. In one embodiment, the contact 152 may extend through the second dielectric layer 150 to connect to the first electrode layer 131 over the flat surface portion of the first dielectric layer 110 having the flat surface 117. The contact 154 may extend through the second dielectric layer 150 to connect to the second electrode layer 135 over the flat surface portion of the first dielectric layer 110 having the flat surface 117. In some embodiments where the tapered portion of the first dielectric layer 110, such as the tapered portions 115a, 115b and 115c, has a substantially flat top surface 128 (e.g., the tapered portion having a trapezoidal shape from a cross-section view) as illustrated in FIG. 1B, the first electrode layer 131 may extend over the flat top surface 128 of one of the tapered portions (e.g., top surface 128 of tapered portion 115c) with the capacitor dielectric 133 and the second electrode layer 135 partially overlapping the first electrode layer 131 over the top surface 128 of the tapered portion, and the contact 152 may extend through the second dielectric layer 150 to connect to the first electrode layer 131 over the top surface 128 of the tapered portion, while the contact 154 may extend through the second dielectric layer 150 to connect to the second electrode layer 135 over the top surface 128 of the tapered portion. The interconnection 162 and 164, for example, may be metal pads. The contacts 152 and 154 and the interconnections 162 and 164 may be formed of a metallic material, such as copper, copper alloy, aluminum or a combination thereof. Other suitable types of metal, alloys or conductive materials may also be useful.

The MIM capacitor stack 130, as described according to various embodiments, may have sloped portions when arranged over the sloped side surfaces of the tapered portions 115a, 115b and 115c of the first dielectric layer 110 and/or grooves 140d and 140e in the first dielectric layer 110, advantageously increasing the effective surface area of the MIM capacitor stack 130, and density of the MIM capacitor in a chip or device. Accordingly, the effective capacitance gain of the MIM capacitor stack 130 in the device may be increased. The sloped shape of the MIM capacitor may increase surface area/capacitance by about 20% or greater compared to a planar MIM capacitor.

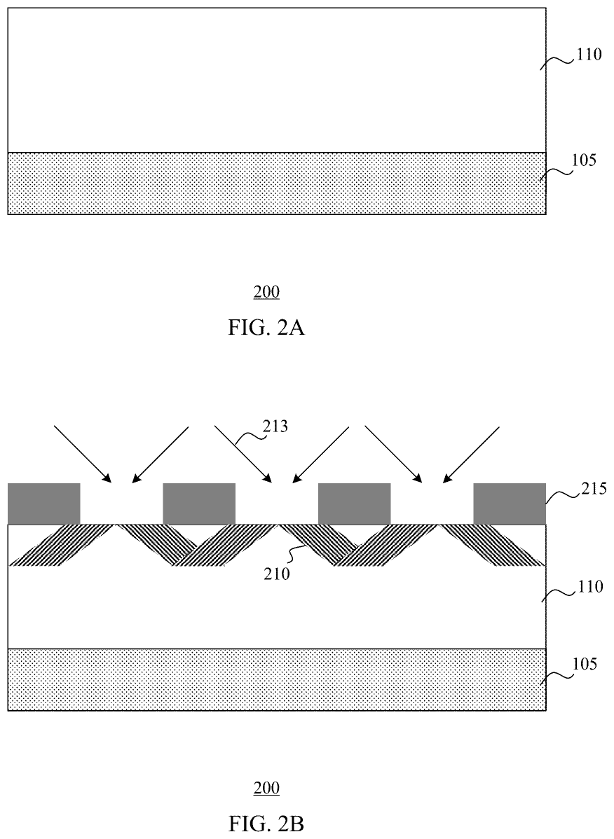

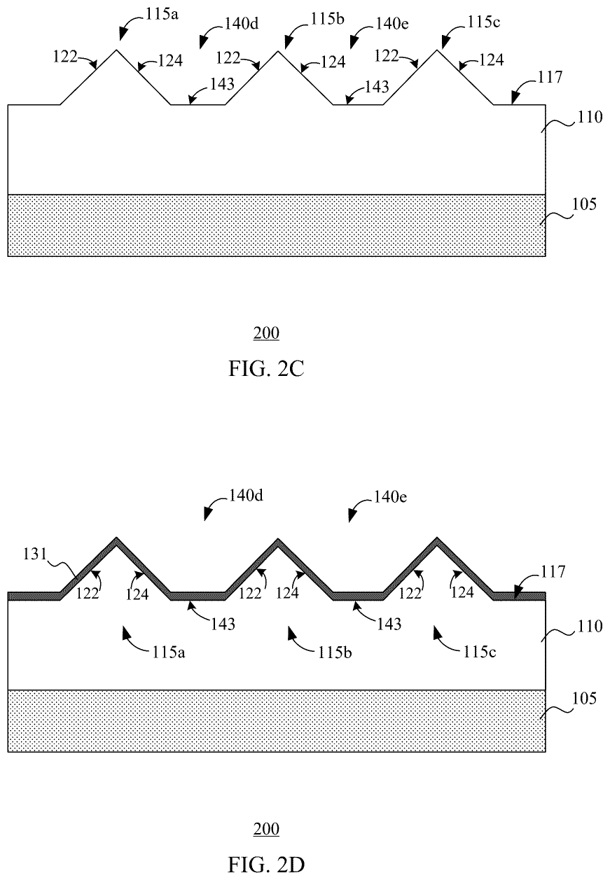

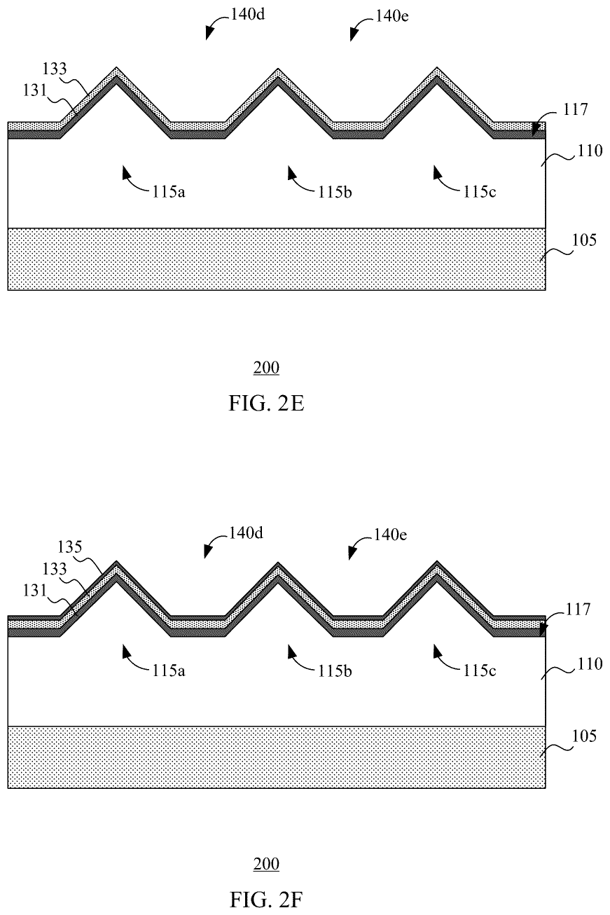

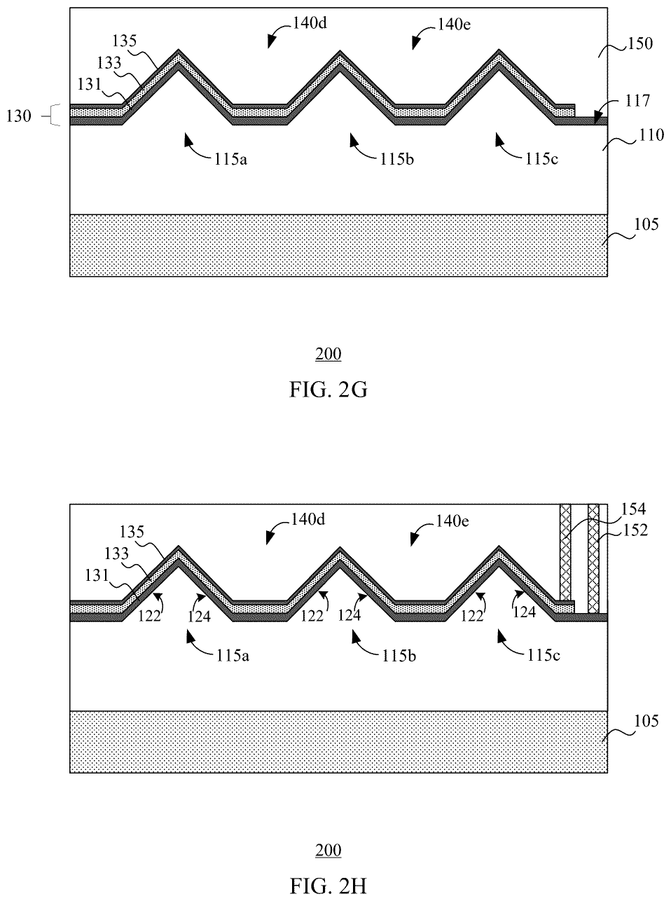

FIGS. 2A-2H show cross-sectional views of a process 200 for forming a structure. The structure, for example, is similar to that described in FIGS. 1A-1B. As such, common elements may not be described or described in detail.

Referring to FIG. 2A, first dielectric layer 110 may be formed over substrate 105. The first dielectric layer 110 may be part of a metallization structure, which may include interconnects disposed in a dielectric formed in a BEOL process. In one embodiment, portions of the first dielectric layer 110 may be removed by lithography, implant and etching processes. Referring to FIG. 2B, a patterned mask layer 215, such as a photoresist, may be formed over the first dielectric layer 110 and an implant process 213 may be performed through the mask layer 215 to create implant damage regions 210 in the first dielectric layer 110. The mask layer 215 may be patterned with openings to allow creation of the implant damage regions 210 during the implant process 213 at locations in the first dielectric layer 110 where portions of the first dielectric layer 110 are to be removed. In one embodiment, the implant process 213 may performed using implants such as Argon (Ar), Phosphorus (P), Arsenic (As) or Boron fluoride (BF2). Other suitable implants may also be used to create the implant damage in the first dielectric layer 110. In one embodiment, the implant process 213 may be a two-directional implant process through each opening in the patterned mask layer 215. The two directions may be opposing directions. For example, the implant process 213 may be performed at an implant angle of about 45° in two directions. The implant angle of the implant process 213 may depend on the desired inclination angle of side surfaces of the tapered portions to be formed. The implant damage regions 210 may correspond to regions in the first dielectric layer 110 in which grooves are to be formed in the first dielectric layer 110 or which surround regions where the tapered portions of the first dielectric layer 110 are to be formed. The implant damage regions 210 may refer to portion(s) of the first dielectric layer 110 having a dopant density of greater than approximately 10²⁰ atoms/cm³. The implant damage regions 210 may have higher etch rate relative to other regions in the first dielectric layer 110 and may be removed, for example, by an etch process. Referring to FIG. 2C, the implant damage regions 210 in the first dielectric layer 110 may be removed by an etch process, such as a reactive ion etch for example, while regions without the implant damage (e.g., undoped regions) may remain unetched. The removal of the implant damage regions 210 portions may form grooves, such as grooves 140d and 140e in the first dielectric layer 110 defined by first and second side surfaces 122 and 124 which are sloped. The remaining regions of the first dielectric layer 110 may form the tapered portions of the first dielectric layer 110, such as tapered portions 115a, 115b and 115c having the first and second side surfaces 122 and 124 which are sloped. The slope or angle of inclination of the first and second side surfaces 122 and 124 may correspond to the implant angle of the implant during the implant process 213. For example, first and second side surfaces 122 and 124 having an angle of inclination of 45° may be formed using an implant angle of about 45°. In one embodiment, the groove 140d and 140e each may be defined by the first side surface 122 and second side surface 124 and bottom surface 143 in the first dielectric layer 110. The profile or shape of the tapered portions 115a, 115b, and 115c and the grooves 140d and 140e may be controlled by the patterned openings and thickness of the mask layer 215 and the implant angle. The energy of the implant process 213 may control the depth of the grooves or height of the tapered portions. Portions of the first dielectric layer 110 damaged by the implant process 213 may also be removed to form a flat surface portion of the first dielectric layer 110 having a flat surface 117. The mask layer 215 may be removed and a clean process may be performed prior to the etch process.

A MIM capacitor stack may be formed over the first dielectric layer 110. In one embodiment, the MIM capacitor stack may be formed over at least a tapered portion, such as the tapered portions 115a, 115b and 115c, and/or a groove, such as the grooves 140d and 140e, in the first dielectric layer 110. Referring to FIG. 2D, a first electrode layer 131 of the MIM capacitor stack may formed over the first side surface 122 and the second side surface 124 of the tapered portions 115a, 115b and 115c. The first electrode layer 131 may line the first and second side surfaces 122 and 124 and the bottom surface 143 of the groove 140d and groove 140e. Referring to FIG. 2E, a capacitor dielectric 133 of the MIM capacitor stack may be formed over the first electrode layer 131 over the first side surface 122 and the second side surface 124 of the tapered portions 115a, 115b and 115c. The capacitor dielectric 133 may line the first electrode layer 131 in the groove 140d and groove 140e. Referring to FIG. 2F, a second electrode layer 135 of the MIM capacitor stack may be formed over the capacitor dielectric 133 over the first side surface 122 and the second side surface 124 of the tapered portions 115a, 115b and 115c. The second electrode layer 135 may line the capacitor dielectric 133 in the groove 140d and groove 140e. The first electrode layer 131, the capacitor dielectric 133 and the second electrode layer 135 of the MIM capacitor stack 130 may be further formed over the flat surface 117 of the flat surface portion of the first dielectric layer 110. The first electrode layer 131, the capacitor dielectric 133 and the second electrode layer 135 may be formed by depositing its constituent material using deposition techniques, such as chemical vapor deposition.

The capacitor dielectric 133 and the second electrode layer 135 may be patterned, for example using lithography and etching processes, such that the capacitor dielectric 133 and the second electrode layer 135 partially overlap the first electrode layer 131 over the flat surface portion having the flat surface 117. A top surface of a portion of the first electrode layer 131 is exposed for coupling to an interconnection. A second dielectric layer 150 may be formed over the MIM capacitor stack 130 and the first dielectric layer 110, as shown in FIG. 2G. The second dielectric layer 150 may be formed, for example, by chemical vapor deposition. The second dielectric layer 150 may fill a remaining space in the groove 140d and the groove 140e. The second dielectric layer 150 may be planarized, for example, by chemical mechanical polishing, to provide a substantially planar top surface.

The process 200 may continue with forming additional interconnects in the BEOL metallization structure and forming contacts 152 and 154 in the second dielectric layer 150 for connection to interconnections 162 and 164 illustrated in FIG. 1A.

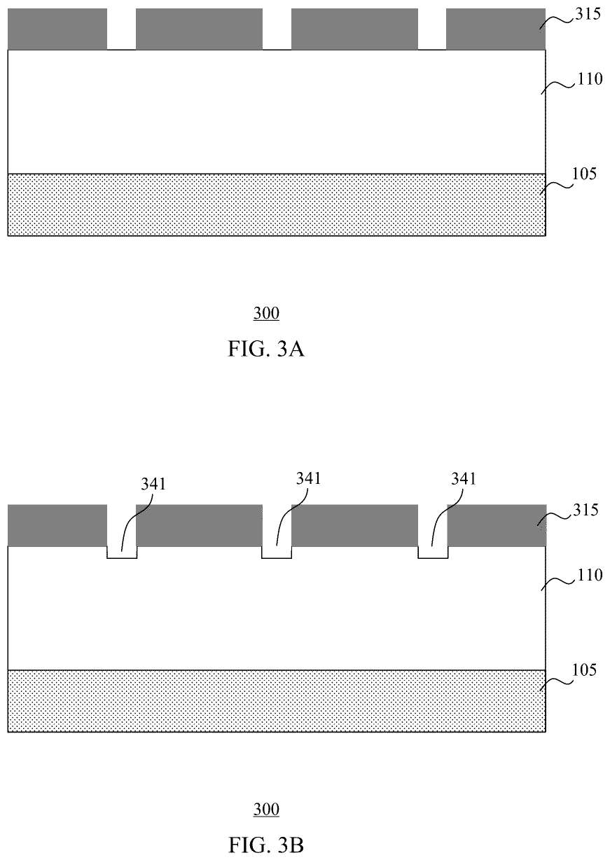

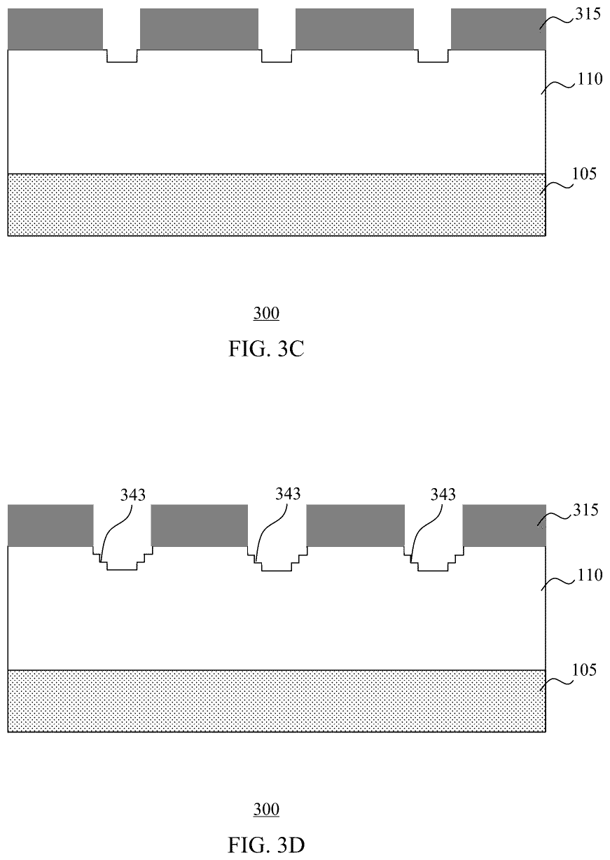

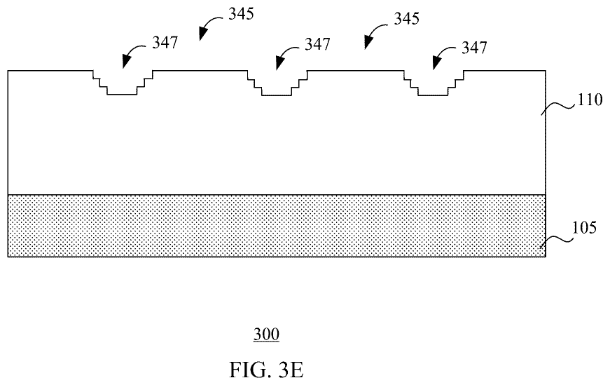

FIGS. 3A-3E show cross-sectional views of a process 300 for forming a structure. The structure, for example, is similar to that described in FIGS. 1A-1B. As such, common elements may not be described or described in detail.

Referring to FIG. 3A, first dielectric layer 110 may be formed over substrate 105. The first dielectric layer 110 may be part of a metallization structure, which may include interconnects disposed in a dielectric formed in a BEOL process.

In one embodiment, portions of the first dielectric layer 110 may be removed by lithography and etching processes in steps or stages to form one or more grooves in the first dielectric layer 110 and one or more tapered portions of the first dielectric layer 110. The lithography and etching processes may be performed with alternating steps of (i) isotropic dielectric etch of the first dielectric layer 110 and (ii) anisotropic etch of a patterned mask. As illustrated in FIG. 3A, a patterned mask layer 315, such as a photoresist, may be formed over the first dielectric layer 110. The mask layer 315 may be patterned with initial openings which correspond to locations in the first dielectric layer 110 where portions of the first dielectric layer 110 are to be removed. The first dielectric layer 110 may be etched using isotropic etch through the patterned mask layer 315 with the initial openings to form initial cavities 341, as illustrated in FIG. 3B. The mask layer 315 may be trimmed to gradually increase the size of the openings in the mask layer 315 so as to be wider than the initial cavities 341 in the first dielectric layer 110, as illustrated in FIG. 3C. The mask layer 315 may be trimmed using anisotropic etch of the mask layer 315. The first dielectric layer 110 may be iteratively etched using isotropic etch through the patterned mask layer 315 which has been trimmed with the wider openings to form stepped sidewalls in the cavities. The trimming of the mask layer 315 and etching of the first dielectric layer 110 may be performed alternately to form grooves 347 with stepped sidewalls or staircase profile 343, as illustrated in FIG. 3D. The relative etch duration of the etch steps of the first dielectric layer 110 may be controlled to obtain a subsequent slope or angle of inclination of the side surfaces of the grooves and tapered portions after a smoothening process (not shown in FIG. 3D). For example, a tapered portion 345 of the first dielectric layer 110 may be formed between two immediately adjacent grooves 347 in the first dielectric layer 110. The mask layer 315 may be subsequently removed. The stepped sidewalls in the grooves 347 may be subsequently smoothen, for example, by a wet etch process, to form the first and second side surfaces 122 and 124 of the grooves (e.g., grooves 140d and 140e) and tapered portions (e.g., tapered portions 115a and 115b) described with respect to FIGS. 1A and 1B. As described, the angle of inclination of the first and second side surfaces 122 and 124 may be controlled through the relative etch duration of the etch steps. The process 300 may continue with the formation of a MIM capacitor stack over the tapered portions of the first dielectric layer 110 and grooves in the first dielectric layer 110, second dielectric layer over the first dielectric layer 110, contacts in the second dielectric layer and interconnections.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

1. A structure, comprising:
a first dielectric layer over a substrate, the first dielectric layer having a tapered portion and a second tapered portion, wherein the tapered portion and the second tapered portion each comprises a first side surface and a second side surface, the first side surface of the tapered portion adjoins the second side surface of the tapered portion to form a first corner, the first side surface of the second tapered portion adjoins the second side surface of the second tapered portion to form a second corner, wherein the first corner of the tapered portion is horizontally adjacent to the second corner of the second tapered portion over the substrate;
a first groove in the first dielectric layer between the tapered portion and the second tapered portion;
a metal-insulator-metal (MIM) capacitor stack arranged over the tapered portion of the first dielectric layer and in the first groove in the first dielectric layer, the MIM capacitor stack comprises a first electrode layer arranged over the first side surface and the second side surface of the tapered portion and in the first groove, a capacitor dielectric arranged over the first electrode layer over the first side surface and the second side surface of the tapered portion and in the first groove, and a second electrode layer arranged over the capacitor dielectric over the first side surface and the second side surface of the tapered portion and in the first groove, wherein the first electrode layer, the capacitor dielectric and the second electrode layer further line the first groove; and
a second dielectric layer over the MIM capacitor stack and the first dielectric layer, the second dielectric layer having a first portion within the first groove, wherein the tapered portion of the first dielectric layer is laterally adjacent to the first portion of the second dielectric layer.

2. The structure of claim 1, wherein the first electrode layer is conformal to the tapered portion, the capacitor dielectric is conformal to the first electrode layer over the tapered portion and the second electrode layer is conformal to the capacitor dielectric over the tapered portion.

3. The structure of claim 1, wherein a lower portion of the tapered portion is wider than an upper portion of the tapered portion.

4. (canceled)

5. The structure of claim 1, wherein the MIM capacitor stack further extends over the second tapered portion of the first dielectric layer, wherein the first electrode layer is further arranged over the first side surface and the second side surface of the second tapered portion, the capacitor dielectric is further arranged over the first electrode layer over the first side surface and the second side surface of the second tapered portion and the second electrode layer is further arranged over the capacitor dielectric over the first side surface and the second side surface of the second tapered portion.

6. The structure of claim 1, wherein the first side surface of the tapered portion and the second side surface of the second tapered portion defines the first groove in the first dielectric layer.

7. The structure of claim 6, wherein the first side surface of the tapered portion and the second side surface of the second tapered portion adjoins a bottom surface of the first groove, and the first electrode layer, the capacitor dielectric and the second electrode layer each are further arranged over the bottom surface of the first groove.

8. The structure of claim 1, wherein the first side surface and the second side surface each has an acute angle with respect to a reference plane which is parallel to a top surface of the substrate.

9. The structure of claim 8, wherein the acute angle is about 30° or greater and less than about 70°.

10. The structure of claim 8, wherein the acute angle is about 45° or greater and less than about 60°.

11. The structure of claim 1, wherein the first dielectric layer further comprises a flat surface, and the MIM capacitor stack further extends over the flat surface, and further comprising a first contact coupled to the first electrode layer over the flat surface and a second contact coupled to the second electrode layer over the flat surface, wherein the first contact and the second contact are arranged in the second dielectric layer.

12. (canceled)

13. A structure, comprising:
a first dielectric layer over a substrate;
a groove having first and second side surfaces and a bottom surface in the first dielectric layer, wherein the first and second side surfaces are sloped and the groove tapers from an upper portion to a lower portion of the groove;
a second groove having first and second side surfaces and a bottom surface in the first dielectric layer, wherein the second side surface of the groove and the first side surface of the second groove adjoin each other to form a corner of a tapered portion of the first dielectric layer, the corner of the tapered portion is horizontally between the groove and the second groove over the substrate;
a metal-insulator-metal (MIM) capacitor stack arranged over the first dielectric layer and conformal to the groove, the MIM capacitor stack comprises a first electrode layer lining the first and second side surfaces and the bottom surface of the groove, a capacitor dielectric arranged over and lining the first electrode layer in the groove and a second electrode layer arranged over and lining the capacitor dielectric in the groove, wherein the first electrode layer, the capacitor dielectric and the second electrode layer each have portions within the groove; and
a second dielectric layer over the MIM capacitor stack and the first dielectric layer, wherein a first portion of the second dielectric layer is disposed within the groove and fills a remaining space in the groove in the first dielectric layer.

14. (canceled)

15. The structure of claim 13, wherein the first electrode layer is conformal to the groove, the capacitor dielectric is conformal to the first electrode layer in the groove and the second electrode layer is conformal to the capacitor dielectric in the groove.

16. The structure of claim 13, wherein the first and second side surfaces of the second groove are sloped and the second groove tapers from an upper portion to a lower portion of the second groove, and the MIM capacitor stack is further conformal to the second groove.

17. The structure of claim 16, wherein the first electrode layer further lines the first and second side surfaces and the bottom surface of the second groove, the capacitor dielectric is further arranged over and lines the first electrode layer in the second groove and the second electrode layer is further arranged over and lines the capacitor dielectric in the second groove.

18. (canceled)

19. A method, comprising:
forming a first dielectric layer over a substrate;
forming a first groove in the first dielectric layer and a tapered portion and a second tapered portion of the first dielectric layer, the first groove is between the tapered portion and the second tapered portion, wherein the tapered portion and the second tapered portion each comprises a first side surface and a second side surface, the first side surface of the tapered portion adjoins the second side surface of the tapered portion to form a first corner, the first side surface of the second tapered portion adjoins the second side surface of the second tapered portion to form a second corner, wherein the first corner of the tapered portion is horizontally adjacent to the second corner of the second tapered portion over the substrate;
forming a metal-insulator-metal (MIM) capacitor stack over the tapered portion of the first dielectric layer and in the first groove in the first dielectric layer, the MIM capacitor stack comprises a first electrode layer formed over the first side surface and the second side surface of the tapered portion and in the first groove, a capacitor dielectric formed over the first electrode layer over the first side surface and the second side surface of the tapered portion and in the first groove, and a second electrode layer formed over the capacitor dielectric over the first side surface and the second side surface of the tapered portion and in the first groove, wherein the first electrode layer, the capacitor dielectric and the second electrode layer further line the first groove; and
forming a second dielectric layer over the MIM capacitor stack and the first dielectric layer, the second dielectric layer having a first portion within the first groove, wherein the tapered portion of the first dielectric layer is laterally adjacent to the first portion of the second dielectric layer.

20. The method of claim 19, wherein forming the tapered portion comprises removing portions of the first dielectric layer to form the first groove and a second groove in the first dielectric layer.

21. The structure of claim 1, wherein the tapered portion of the first dielectric layer is higher than a bottommost portion of the second electrode layer in the first groove.

22. The structure of claim 13, wherein the MIM stack is further conformal to the tapered portion, and the first portion of the second dielectric layer is laterally adjacent to the tapered portion of the first dielectric layer.
